(19) United States
(12) Patent Application Publication
(10) Pub. No.: US 2006/0070979 A1
(43) Pub. Date: Apr. 6, 2006

(54) Using ozone to process wafer like objects

(76) Inventors: Kurt K. Christenson, Minnetonka, MN (US); Philip G. Clark, Eden Prairie, MN (US)

Correspondence Address: KAGAN BINDER, PLLC, SUITE 200, MAPLE ISLAND BUILDING, 221 MAIN STREET NORTH, STILLWATER, MN, 55082, US

(21) Appl. No.: 11/226,918

(22) Filed: Sep. 13, 2005

Related U.S. Application Data
(60) Provisional application No. 60/610,702, filed on Sep. 17, 2004.

(51) Int. Cl. B08B 6/00; C03C 15/00; H01L 21/306

(52) U.S. Cl. 216/83; 134/1.3; 134/26; 156/345.11

(57) ABSTRACT

The present invention relates to methods of processing wafer-like objects (e.g., having an exposed copper feature and/or including low-k dielectric material) with ozone. In certain preferred embodiments, a base is also used to process the wafer-like object(s).

### PRIORITY CLAIM

The present non-provisional patent Application claims priority under 35 USC § 119(e) from U.S. Provisional Patent Application having Ser. No. 60/610,702, filed on Sep. 17, 2004, by Christenson et al. and titled USING A COMBINATION OF OZONE AND A BASE TO PROCESS WAFER LIKE OBJECTS WITH EXPOSED COPPER, wherein the entirety of said provisional patent application is incorporated herein by reference.

### FIELD OF INVENTION

The present invention provides low cost, environmentally friendly cleaning and surface treatments for a wide variety of applications. The present invention facilitates using ozone to process wafer-like objects, e.g., semiconductor wafers or other microelectronic structures, having surfaces with exposed copper. One application includes stripping resist and/or post-ash cleans on back end of line (BEOL) wafers with exposed copper. The principles of the present invention could also be practiced whenever copper is being cleaned. The present invention would be of interest in the manufacture of printed circuit boards incorporating copper features. Another application involves removing organic material and/or organic residue material from wafers incorporating a low k dielectric material.

### BACKGROUND

Prior to the invention, it was problematic to use ozone chemistry to process wafer-like objects having exposed copper. Especially in the presence of water, ozone tends to corrode Cu metal, particularly when CO₂ is present (See “Atlas of Electrochemical Equillibria in Aqueous Solutions,” editor Marcel Pourbaix (National Association of Corrosion Engineers, Houston, 1974), the entirety of which is incorporated herein by reference. Referred to hereinafter as “Pourbaix”). At page 390, Pourbaix notes that “dissolved carbonic acid in the water prevents the formation of a protective film of oxide.” Pourbaix also shows at page 389 that Cu corrosion occurs below pH 7 in oxidizing solutions, and even tiny traces of CO₂ would move the system into the corrosive regime.

The integration of porous low-k materials in advanced technology nodes (<65 nm) requires the development of non-damaging integration etch, ash and clean processes. Traditional plasma ash processes using oxidizing or reducing chemistries can significantly damage the low-k material through Si—C bond attack and film densification. Photoresist removal using traditional plasma ash chemistries leads to severe degradation of low-k dielectric properties, including increases in k-value and changes in critical dimensions. Restoration processes using various silyating agents, for example, hexamethydisilazane (HMDS) have been used to partially restore the dielectric properties of films that have been ashed. Low-k restoration processes using HMDS in the vapor phase or as a co-solvent in supercritical CO₂ have been demonstrated for spin-on porous MSQ films (See, e.g., P. G. Clark, et al., “Cleaning and Restoring k-Value of Porous MSQ films”, Semiconductor International, August 2003; P. G. Clark, et al., “Post Ash Residue Removal and Surface Treatment Process for Porous MSQ”, International Sematech Wafer Clean & Surface Prep Workshop, May 2003; and G. B. Jacobson, et al., “Cleaning of Photoresist and Etch Residue from Dielectrics using Supercritical CO₂”, International Sematech Wafer Clean & Surface Prep Workshop, May 2003, the entirety of each document being incorporated herein by reference). These processes have partially restored the k-value to within 10% of the as-deposited material. However, these processes do not fully restore the k-value of the as-deposited low-k film. Desired requirements call for maximum changes in k-value of no more than 2.5% for strip+residue removal processes, with the goal to completely eliminate any detrimental effects from cleaning and rework processes. As a result, non-damaging photoresist removal has become a key challenge in ultra-low k integration.

Other related documents include S. Nelson, “Reducing Environmental Impact with Ozone Based Processes,” Environmental Issues in the Electronics and Semiconductor Industries, ed. L. Mendicino (Electrochemical Society, 2001) pp. 126-133, and PCT Patent Publication WO 02/04134 A1, the entirety of each document being incorporated herein by reference.

### SUMMARY OF THE INVENTION

Pourbaix shows at page 389 that Cu is passivated from pH 7 to 12.5. The present invention appreciates, therefore, that it would be desirable to carry out ozone treatments in a basic environment in order to reduce corrosion of copper in the presence of ozone, particularly when water is present. Numerous benefits result when carrying out ozone treatments in a basic environment. Corrosion of copper is dramatically reduced when ozone processes occur under basic conditions. Indeed, useful, but moderately acidic ingredients such as CO₂ may be present without undue corrosive effects. In short, pH adjustment into the basic range allows the use of ozone when cleaning Cu BEOL wafers. The ozone itself can be used to strip resist, and the ozone-base mixture can act something like APM (NH₄OH:H₂O₂:H₂O) to aid in cleaning post-ash clean residues.

The presence of a base also helps remove so-called carbonized crust layers. In typical post-etched photoresist films, a carbonized crust layer tends to be formed after etching as a result of exposure to highly energetic RIE plasmas. The crust layer removal rate is very slow using ozone only. However, the short-lived radical species produced during the breakdown of O₃ in basic solutions are very reactive, and can attack and facilitate removal of the crust layer. FIG. 2 shows the skin 210 left on the wafer 200 after the bulk of the resist was dissolved by a photoresist stripping chemistry for wafers with exposed copper interconnects commercially available under the trade designation JTB ALEG 820 from J. T. Baker Electronic Materials, Phillipsburg, N.J. The present invention was able to remove this skin 210. This removal may be due to the production of reactive radical species during the breakdown of ozone by the base.

We have examined the effectiveness of an HMDS restoration process on an ultra-low k (ULK) CVD organo-silicate glass (OSG) material. Our results indicate that restoration only improves with increasing material porosity (e.g., k=2.2 films), in fact, we did not see any improvement for the k=2.5 film. Consequently, a replacement to the damaging plasma ash process was examined using principles of the present invention. The principles of the present invention may also be used in the context of performing cleaning processes for porous, low-k dielectric materials with reduced damage of the dielectric materials.

Significantly, the present invention may be used to strip photoresist from wafers incorporating low k dielectric materials with very little, if any, changes in dielectric properties or critical dimensions. For example, as discussed further below, a treatment of the present invention was used to strip photoresist from a wafer incorporating a CVD organo-silicate glass material (OSG) low k film, and the treatment yielded no changes in the low-k dielectric properties or in critical dimensions. A preferred mode of practice involves using an “all-wet” photoresist strip developed using DIO₃ optionally co-dispensed in a batch spray processor with an aqueous base that is used to wet the wafers. The use of the aqueous base is more desirable when the wafer(s) being treated have exposed copper. Treatments with DIO₃ offer significant reduction in chemical cost and hazardous waste generation as compared to commercial formulations. The ozone process results in only de minimis change in k-value relative to the as-deposited film. In addition, electrical parametric data on patterned test structures indicate that the leakage current is much lower for films processed with ozone as compared to films processed with a reducing plasma ash.

According to one aspect of the present invention, a method of processing one or more wafer-like objects includes the step of causing ozone to contact the one or more wafer-like objects at a pH greater than about 7.5.

According to another aspect of the present invention, a method of processing one or more wafer-like objects includes the step of causing ozone to contact the one or more wafer-like objects while the wafer-like objects are wetted with an aqueous base.

According to another aspect of the present invention, a system for treating a wafer-like object includes a chamber in which the wafer-like object is positioned during a treatment, a first pathway through which an ozone-containing material is dispensed into the chamber, a second pathway through which an aqueous base is dispensed into the chamber in a manner effective to wet the wafer-like object, and program instructions causing the ozone-containing material and the aqueous base to be dispensed into the chamber in a manner such that ozone contacts the wafer-like object under alkaline conditions.

According to another aspect of the present invention, a system for treating a wafer-like object includes a chamber in which the wafer-like object is positioned during a treatment, a first pathway through which an ozone-containing material is dispensed into the chamber, a second pathway through which an aqueous base is dispensed into the chamber in a manner effective to wet the wafer-like object, and program instructions causing the ozone-containing material and the aqueous base to be co-dispensed into the chamber during at least a portion of the treatment.

In preferred embodiments, the wafer-like object includes an exposed copper feature.

According to another aspect of the present invention, a system for treating a wafer-like object including an exposed copper feature includes a chamber in which the wafer-like object is positioned during a treatment, a first fluid material dispensed into the chamber, the first fluid material including ozone, and a second fluid material separately dispensed into the chamber, the second fluid material having a pH greater than about 7.5 and being dispensed in a manner effective to help establish a basic environment proximal to the exposed copper feature.

According to another aspect of the present invention, a system for treating a wafer-like object including an exposed copper feature includes a chamber in which the wafer-like object is positioned during a treatment, a first fluid material dispensed into the chamber, the first fluid material including ozone, and a second fluid material separately dispensed into the chamber, the second fluid material including an aqueous base.

According to another aspect of the present invention, a method of treating a wafer-like object having an exposed copper feature includes the steps of positioning the wafer-like object on a rotating support in a processing chamber, spraying an aqueous base onto the wafer-like object, and dispensing a material including ozone into the processing chamber.

According to another aspect of the present invention, a method of treating a wafer-like object including a low-k dielectric material includes the step of causing ozone to contact the one or more wafer-like objects.

### BRIEF DESCRIPTION OF THE DRAWINGS

FIG. 1A shows a schematic view of a batch spray processor that can be used to carry out the present invention.

FIG. 1B shows a schematic view of the ozone dispense mechanism of the batch spray processor shown in FIG. 1A dispensing ozone-saturated deionized water onto the rotating turntable from the bottom of the center spray post while the wafers can be heated/wetted using a basic deionized water mixture dispensed directly onto the wafers according to the present invention.

FIG. 2 shows a schematic view of a carbonized skin on a wafer after the wafer was exposed a highly energetic RIE plasma stripping chemistry.

FIG. 3 is a photomicrograph showing a side-view of a wafer processed according to Example 1 with a DIO₃ solution containing CO₂, but not containing a base.

FIG. 4 is a photomicrograph showing a side-view of a wafer processed according to Example 1 with a DIO₃ solution containing CO₂ and a base such that the solution was dispensed at a pH of 11.8.

FIG. 5A shows a schematic view of a pre-DIO₃ process, SEM image of a low-k dielectric structure having photoresist thereon.

FIG. 5B shows a schematic view of a post-DIO₃ process, SEM image of a low-k dielectric structure having complete photoresist removal with no apparent change in critical dimensions.

FIG. 6 shows leakage current data for wet strip and plasma ash processes.

### DETAILED DESCRIPTION

As mentioned, ozone tends to corrode Cu metal, particularly when CO₂ is present and especially in the presence of water. Unfortunately, it is very desirable to add CO₂ to ozonated water as a radical scavenger to increase the lifetime of the ozone in solution. Although it might seem possible to avoid adding CO₂ to the ozonated water and just tolerate the resulting lower concentrations of O₃, this is not practical. First, CO₂ is nonetheless produced when organics are oxidized. This in situ generation of CO₂ would tend to move the system into or toward the corrosion region. Consequently, avoiding CO₂ is not desirable, nor is it a robust solution to the corrosion problem, particularly when bulk organics are present.

A typical ozone treatment of the present invention involves causing ozone to contact one or more wafers positioned in a suitable process chamber. The ozone may be introduced to the process chamber as a gas and/or as a solute in solution. Introducing ozone as a constituent of a DIO₃ solution is preferred. As used herein, “DIO₃” refers to aqueous compositions including water (preferably deionized), dissolved ozone, and optionally one or more other optional ingredients. Examples of other optional ingredients that may be incorporated into a DIO₃ composition include a base, a radical scavenger such as carbon dioxide, a corrosion inhibitor such as BTA (benzotriazole, a common corrosion inhibitor for Cu) and/or uric acid, combinations of these, and the like. Koito et al. has described the use of uric acid as a corrosion inhibitor in “Effective and Environmentally Friendly Remover for Photo Resist and Ashing Residue for Use Cu/Low-k Process (IEEE Tran. Semi. Mfg. 15, 4, November 2002, p. 429), incorporated herein by reference in its entirety. See also United States Patent documents 2004/0029051, 2003/0130147, 2003/0173671, 2003/0083214, 2003/0003713, 2002/0155702, 2002/0037479, and 2002/0025605, each of which is incorporated herein by reference in its respective entirety. In some modes of practice, the addition of a corrosion inhibitor could allow operation at lower pHs than is possible with a weak base alone. In some modes of practice, a corrosion inhibitor could allow operating without an added base, particularly if CO₂ were not deliberately added to the DIO₃ and/or the wafers had a low organic load.

DIO₃ solutions generally may include from about 1 ppm to about 100 ppm ozone on a weight basis relative to the water in the solution. Generally, ozonated solutions containing more than about 20 ppm ozone are prepared by dissolving ozone in water under pressure and then dispensing the resultant solution into the process chamber. U.S. Pat. Nos. 5,971,368; 6,235,641; 6,274,506; and 6,648,307, incorporated herein by reference in their respective entireties, describe methods and systems for preparing DIO₃ solutions.

A wide variety of base(s) may be used in the practice of the present invention. In most embodiments, it is preferred that that the base not unduly react with Cu. Aqueous ammonia by itself, for instance, might tend to complex Cu++ ions unduly in some modes of practice. In such instances, it may be desirable to use the aqueous ammonia in combination with a corrosion inhibitor. Another factor affecting performance concerns the strength of the base. The base should be strong enough to provide a treatment regime in which the pH is greater than 7. It is also desirable that the base be strong enough to neutralize CO₂ that is generated during a treatment. Yet, it may be preferred that the base not be too strong as ozone might break down too rapidly in the presence of a base that is too strong, and/or not too strong such that the solution pH would be too far into the regime of corrosion, i.e., above pH approximately 12.5. Balancing these concerns, a base is selected and used in appropriate amounts such that the basic solution as dispensed onto the wafer-like objects 18 (see below) has a pH in the range of from about 7.0 to about 12.5, preferably about 8 to about 11, more preferably about 9. Lower pH, e.g., from about 7.0 to about 9 may be beneficially practiced when the base solution is buffered. Higher pH, e.g., from about 11 to about 12.5, may be beneficially practiced when heavier organic load is present inasmuch as CO₂ tends to be produced when the ozone consumes the organics.

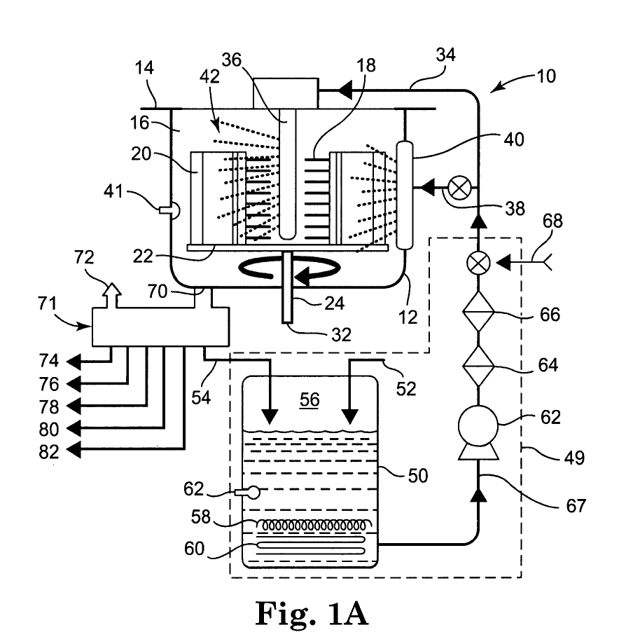

The desired pH and base depends on the delivery method. If the base and DIO₃ are blended in a mixing manifold remote from the wafer surface, the O₃ could break down substantially on its way to the wafer surface. Lower pHs in the alkaline regime would generally be preferable in such remote-mix situations. Higher pH operation is more practical when dispensing ozonated water downward onto the turntable 22 of a spray processor 10 in accordance with the treatment technique described below in connection with FIGS. 1A an 1B, wherein the ozone initially encounters the base primarily at the wafer 18 surfaces.

KOH, and the alkaline-metal free tetramethyl ammonium hydroxide (TMAH), are preferred as both react only minimally with Cu metal and have both been used successfully as described in the Examples below. Yet, because KOH contains alkali metals, TMAH is more preferred. Other examples of suitable bases include tetraethyl ammonium hydroxide, tetrabutyl ammonium hydroxide, combinations of these, and the like. Optionally, the base solutions of the present invention may be buffered to achieve one or more desired objectives such as to help stabilize the pH toward treatment by-products and/or to help enhance the lifetime of the base solution.

The present invention may be used to process multiple wafer-like objects simultaneously, as occurs with batches of wafers when being processed in a spray processing tool such as the MERCURY® or ZETA® spray processors commercially available from FSI International, Inc., Chaska, Minn. The present invention may also be used in single wafer processing applications where the wafers are either moving or fixed or in batch applications where the wafers are substantially stationary.

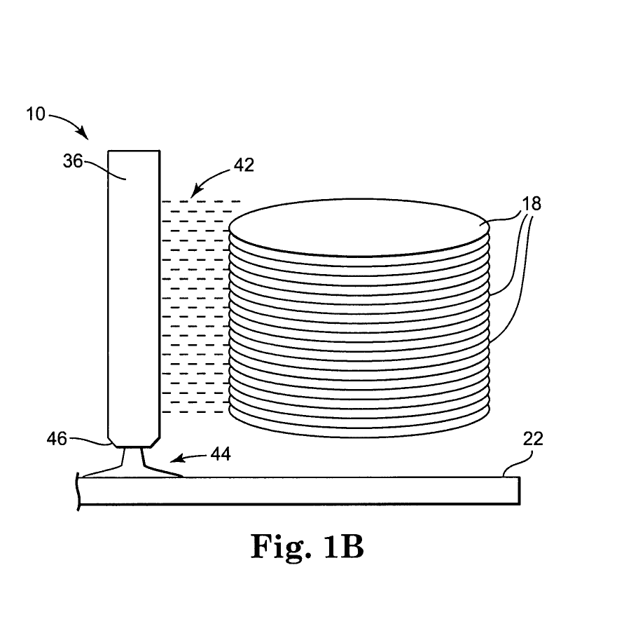

Because a base may tend to react with and consume the ozone, it is preferred that the ozone and base(s) be separately introduced into the process chamber. FIGS. 2A and 2B show one example of equipment useful for accomplishing this. FIG. 2A shows a schematic view of a batch spray processor 10 showing main system components including chemical mixing manifold 49, recirculation tank 71, and process bowl 12. The equipment 10 is a schematic representation of a spray processing tool such as that included in a MERCURY® or ZETA® spray processor commercially available from FSI International, Inc., Chaska, Minn. Equipment 10 generally includes a tank 12 and lid 14 defining a processing chamber 16. Wafer-like objects 18 are positioned in carriers 20 (e.g., TEFLON® cassettes), which in turn are held upon rotating turntable 22 by turntable posts (not shown). Turntable 22 is coupled to motor-driven shaft 24. One or more chemicals may be supplied from supply line(s) 32 and dispensed into processing chamber 16 through the turntable posts (not shown). One or more chemicals may also be supplied from supply line(s) 34 and dispensed into processing chamber 16 directly onto the wafers 18 and/or directly onto turntable 22 through center spray post 36. For example, a supply line 34 can be fluidly coupled to a chemical mixing manifold 49. Chemical mixing manifold can include chemical supply lines 67 and 68. Chemical supply line 67 can include filters 64 and 66, pump 62, and be fluidly coupled to chemical supply tank 50. Chemical supply tank can be supply with process chemical from recirculation drain 54 and fresh chemical makeup 52. A nitrogen blanket 56 can be used in the headspace of tank 50. To control temperature of the process chemical in tank 50, tank 50 can include a heating coil 58, cooling coil 60, and temperature probe 62. Chemical supply line 68 can supply, e.g., nitrogen and Di water rinse. One or more chemicals may also be supplied from supply line(s) 38 and dispensed into processing chamber 16 through side bowl spray post 40. Tank 12 can also include a side-bowl temperature probe 41. After supplying chemical to processing chamber 16, any unused chemical can enter drain 70 into recirculation tank 71. From recirculation tank, the chemical can be directed to a variety of outlets such as recirculation drain 54, exhaust 72, DI drain 74, auxiliary 76, auxiliary 78, auxiliary 80, and auxiliary 82. The configuration and use of equipment 10 has been further described in U.S. Pat. Nos. 5,971,368; 6,235,641; 6,274,506; and 6,648,307, as well as in Assignee's co-pending U.S. patent application titled ROTARY UNIONS, FLUID DELIVERY SYSTEMS, AND RELATED METHODS in the names of Benson et al., filed Mar. 12, 2004, and having U.S. Ser. No. 10/799,250, said co-pending application being incorporated herein by reference in its entirety.

FIG. 1B shows one representative mode of practice of using the equipment 10 in accordance with the present invention. A basic solution 42 comprising one or more bases dissolved in deionized water is dispensed onto wafer-like objects 18 from center spray post 36. This wets the wafer surfaces with the basic chemistry. In the meantime, DIO₃ 44 is splashed down onto the rotating turntable 22 from the bottom 46 of center spray post 36. In this “splashdown” approach, ozone gas will then tend to outgas from the DIO₃. A significant fraction of O₃ evaporates out of solution and oxidizingly contacts the wafer surfaces in the presence of the alkaline chemistry. The O₃ in the gas phase readily dissolves into the thin layers of liquid on the wafers. The thin layers allow rapid diffusion of O₃ to the wafer surface providing good mass transport and little time for degradation of the O₃ by the base. Specific examples of carrying out this approach are described in the examples, below.

The following examples were carried out in a MERCURY® MP spray processor as configured in FIGS. 1A and 1B and commercially available from FSI International, Inc., Chaska, Minn.

### EXAMPLE 1

Introducing DIO₃ via Splashdown and using Aqueous KOH as the Base

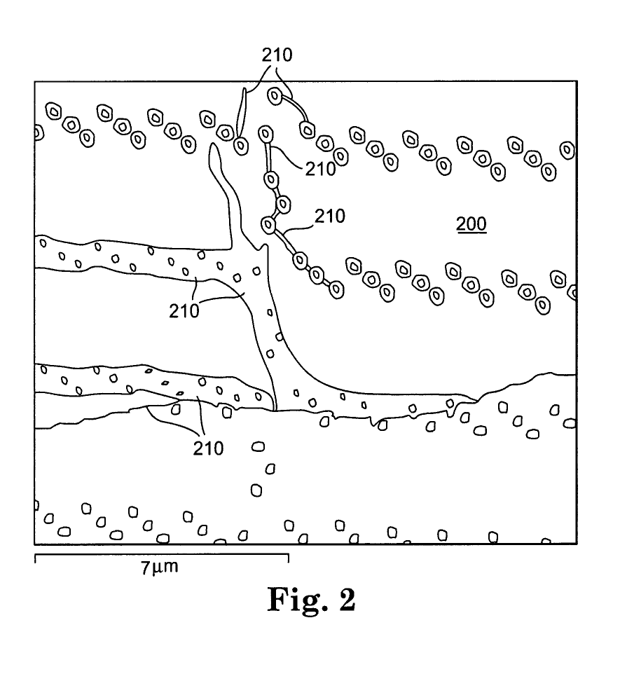

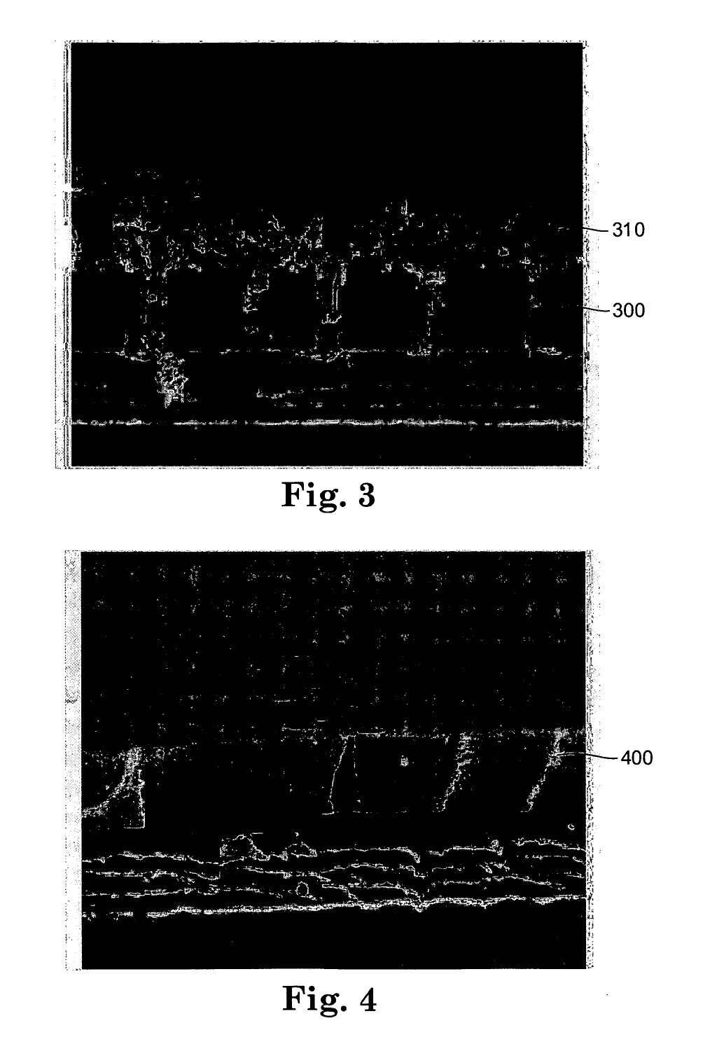

One 200 mm wafer containing exposed, patterned copper and photoresist residue and 99 bare silicon filler wafers were positioned inside the process chamber. DIO₃ solution was prepared containing approximately 80 ppm ozone in deionized water. The DIO₃ solution also contained 40 ppm CO₂. With the turntable rotating at 500 RPM, the DIO₃ was continuously dispensed down onto the turntable (See FIG. 1B) from the bottom of the center spray post. The DIO₃ was supplied at 10 lpm and 20° C. As the DIO₃ was dispensed down onto the turntable, the wafers were sprayed with aqueous base according to a repeated, 80-second cycle in which the base was sprayed for 50 sec of the cycle. The aqueous base was dispensed from the center spray post onto the wafers at 9.1 lpm and 85° C. During the remaining 30 sec of the cycle, the wafers were spun without spraying the aqueous base to allow O₃ to diffuse to the wafer surfaces. The base mixture was formed by combining 300 cc/min of 100:1 by wt KOH at 20° C. and 1800 cc/min deionized water at 95° C. in a manifold prior to dispense. This was co-dispensed from the center spray post with a separate, approximately 7 lpm stream of deionized water. The two streams of wet chemistries were dispensed so as to atomizingly impact each other outside the spray post. The resultant basic solution thus contained approximately 0.35 g/l KOH (0.006 molar) for a pH of 11.8. An identical process was carried out, except no KOH was added to the liquid sprayed on the wafers. FIGS. 3 and 4 show the Splashdown process (described above in connection with FIGS. 1A and 1B) without and with KOH addition, respectively. As can be seen by comparing FIGS. 3 and 4, the use of KOH (FIG. 4) substantially eliminated any detectable Cu corrosion, as measured by Scanning Electron Microscopy. FIG. 3 shows wafer 300 having Cu corrosion 310, whereas FIG. 4 shows wafer 400 having any detectable Cu corrosion substantially eliminated.

### EXAMPLE 2

Introducing DIO₃ and using Aqueous TMAH as the Base

The procedure of Example 1 was used, except that 150 cc/min of a solution containing 1 part by weight of TMAH in 67 parts by weight deionized water was combined with 1800 cc.min DI water in the manifold. The resultant base thus contained approximately 0.25 g/l TMAH (0.003 molar) for an approximate pH of 11.5. Corrosion data obtained from this procedure is described below.

### EXAMPLE 3

Introducing DIO₃ via Splashdown and using Aqueous TMAH as the Base and Uric Acid as the Corrosion Inhibitor

The procedure of Example 2 was used, except that 0.45 grams/min of Uric Acid was added to the 150 cc/min of TMAH solution that was combined with 1800 cc/min DI water in the manifold.

Table I shows the copper loss as measured by x-ray fluorescence spectroscopy on blanket copper wafers processed with DIO₃ only, DIO₃+TMAH (Example 2), and DIO₃+TMAH+Uric Acid (Example 3), yielding 33.5 Å, 10.7 Å, and 1.0 Å, respectively. The slight haze observed for Examples 2 and 3 is believed to be a surface oxide that is easily removed using a dilute acid chemistry, e.g., dilute HF or commercial chemical solutions, e.g., those available under trade designations ST-250™ from ATMI, Danbury, Conn., or DEERCLEAN™ LK-1 from Kanto Chemical Company, Inc., Tokyo, Japan.

TABLE I
Cu Loss Measurements for DIO₃ Photoresist Strip Process.

| Process | Blanket Cu Loss (Å) | Surface Oxidation |
|---|---|---|
| DIO₃ | 33.5 | Visible Surface Oxidation |
| DIO₃ + TMAH | 10.7 | Slight Haze |
| DIO₃ + TMAH + Uric | 1.0 | Slight Haze |
| Acid | | |

The principles of the present invention may also be used in the context of performing cleaning processes for porous, low-k dielectric materials with reduced damage of the dielectric materials.

Residue removal from low-k material for BEOL applications preferably involves automated tools to be very flexible in terms of the chemical compatibility of the materials of construction, process temperatures and chemical dispense times. Equipment 10 shown in FIGS. 1A and 1B may be used. This system is a batch spray processor 10 that utilizes centrifugal force for enhanced particle removal and drying. The process chemistry can be dispensed via center 36 and side spray posts 40 from a fresh 52 or recirculated 54 source. The chemicals are stored and dispensed under a nitrogen atmosphere to minimize chemical degradation and maximize bath life. The wafers 18 can be rotated both clockwise and counter-clockwise to optimize uniformity. In addition, the chemical temperature is monitored at the chemical heater 58 and in the process bowl 12 to accurately control the on-wafer chemical temperature.

The ozone process includes the step of dissolving ozone in deionized water at elevated pressures to achieve 120 ppm concentration at room temperature. As shown in FIG. 1B, the ozonated water (DIO₃) 44 is dispensed through the bottom 46 of the center spraypost 36 onto the rotating turntable 22 while simultaneously dispensing heated deionized water mixture 42, optionally containing base and/or containing corrosion inhibitors, directly onto the wafers 18. The supersaturated DIO₃ 44 is dispensed onto the spinning turntable 22 where the ozone outgases and remains in the sealed process chamber 16. The resulting wafer 18 temperature preferably is approximately 70° C. and the ozone dispense time is less than 30 minutes per 100 wafer batch.

### Low-k Film Examples

Initial studies used blanket low-k films deposited on Si substrates to allow determination of film damage. Films were prepared using a plasma enhanced oxygen-organosilane capacitive discharge to thicknesses of ˜6300 Å. The plasma anneal is used to drive out film porogens and attain low porosity. Differing low-k films of k=2.5 and 2.2 were obtained by altering the post deposition plasma anneal. All blanket films were given a partial etch back to ˜3700 Å, emulating a typical etch process. No photoresist was coated onto the blanket films for these studies. The strip conditions were setup to remove the targeted photoresist (4100 Å of 248 nm resist), and processed on the ULK films. Patterned wafers were then used to examine electrical leakage. Here films were deposited to a thickness of ˜6300 Å, and patterned using the same resist conditions. Films were partially etched, using a CHF₃/CF₄N₂ chemistry, to ˜50% of the original film thickness.

Blanket ULK CVD OSG films were processed with 1) etch only; 2) etch+ash; and 3) etch-ash-HMDS-clean-HMDS. All samples were annealed to 400° C. and the film thickness data and k-values are shown for k=2.2 and k=2.5 films in Table II. The results indicate that as the film porosity increases the damage from the ash process is more pronounced. Specifically, the k-value increased to 2.91 and 2.82 for the k=2.2 and k=2.5 films, respectively. In addition to k-value increase the films also showed significant film densification, −28% for the k=2.2 and −12% for the k=2.5 films.

The clean and HMDS restoration process showed a 9% decrease in k-value for the k=2.2 film, decreasing the k-value from 2.91 to 2.66. However, for the more dense k=2.5 film the clean and HMDS restoration process did not provide any significant k-value reduction.

TABLE II
Thickness and k-Value Measurements for Plasma Ash Processes.

| Low k | Process | Thickness (Å) | k-Value |
|---|---|---|---|
| k = 2.2 | Etch-Anneal | 3830 | 2.02 |
| | Etch-Ash-Anneal | 2764 | 2.91 |
| | Etch-Ash-HMDS-Clean- | 2716 | 2.66 |
| | HMDS-Anneal | | |
| k = 2.5 | Etch-Anneal | 3573 | 2.46 |
| | Etch-Ash-Anneal | 3159 | 2.82 |
| | Etch-Ash-HMDS-Clean- | 3200 | 2.78 |
| | HMDS-Anneal | | |

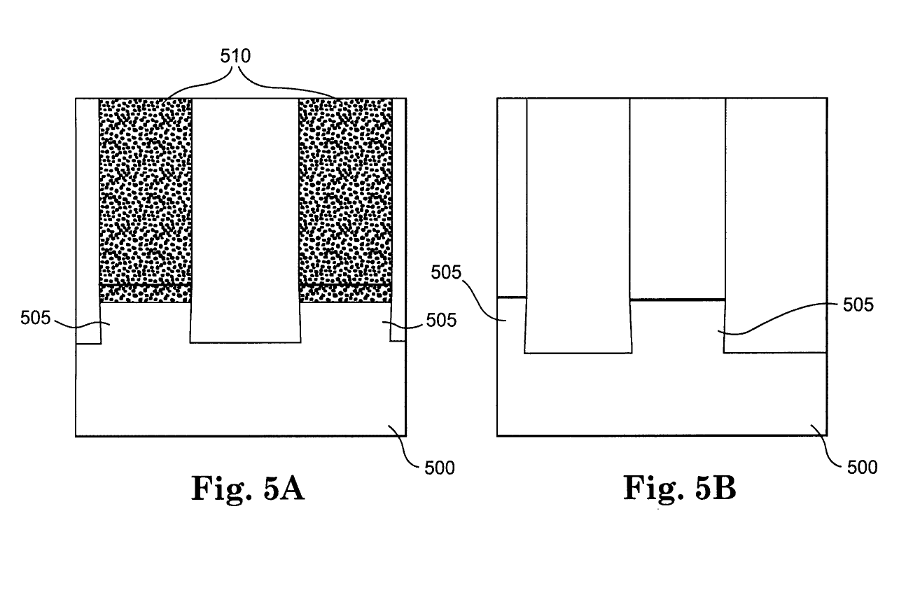

In contrast to the plasma ash approach described in connection with Table II, a wet strip process in accordance with the present invention, which selectively removes the photoresist without the need of a plasma ash, was used to reduce the damage to the low k material during the strip/clean processes. Short-loop pattern test structures were prepared with photoresist on ULK CVD OSG. FIGS. 5A and 5B illustrate SEM images that were obtained for the pre- and post-ozone processed structures. The pre-ozone process (FIG. 5A) shows photoresist material 510 on, e.g., raised structure 505 of low-k dielectric structure 500. The post-ozone process (FIG. 5B) shows complete photoresist removal from low-k dielectric structure 500 with no apparent change in critical dimensions of, e.g., raised structure 505.

Table III shows the film thickness and k-value data for films which were processed with 1) etch only and, 2) etch+wet strip. Both splits were annealed to 400° C. The results indicate that the wet-strip process does not significantly decrease film thickness (<2%) or increase k-value (<2%).

TABLE III
Thickness and k-Value Measurements for Wet Strip Processes.

| Low k | Process | Thickness (Å) | k-Value |
|---|---|---|---|
| k = 2.2 | Etch-Anneal | 3830 | 2.02 |
| | Etch-Strip-Anneal | 3742 | 2.07 |
| k = 2.5 | Etch-Anneal | 3573 | 2.46 |
| | Etch-Strip-Anneal | 3536 | 2.49 |

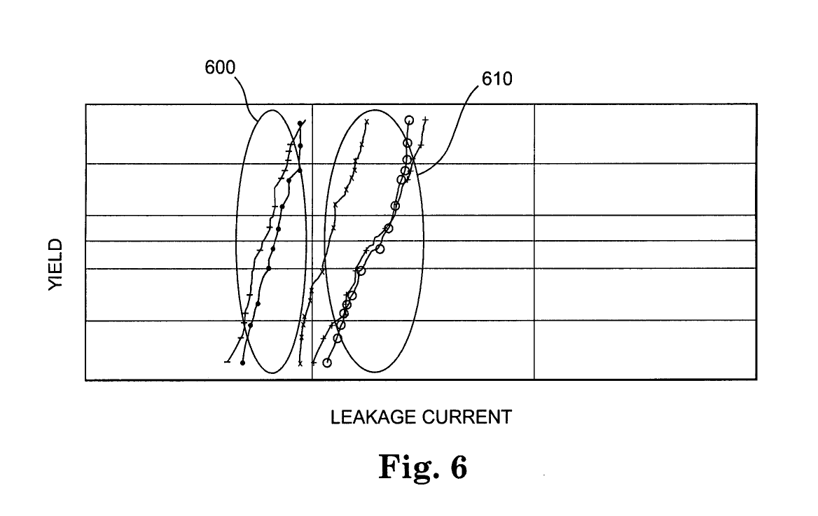

Electrical parametric data were then taken on the short-loop test structures. FIG. 6 shows the decrease in leakage current for the splits processed with the wet-strip relative to those processed with a plasma ash. Both processes yield tight current distribution; however, the wet strip process yields lower leakage current. Circled area 600 indicates data obtained from wet-strip DIO₃ processing and circled area 610 indicates data obtained from plasma ash processing.

These electrical test structures did not have exposed copper. Therefore, blanket copper wafers were used to assess copper oxidation using the DIO₃ process. Blanket copper wafers with an average starting thickness of ˜950 Å were used for the copper loss study and measured using a Thermo Noran GXRS X-Ray Fluorescence (XRF) system. The Pourbaix diagram for the copper/copper oxide system in water indicates that copper oxide is soluble for acidic mixtures (see, e.g., “Atlas of Electrochemical Equilibria in Aqueous Solutions,” editor Marcel Pourbaix (National Association of Corrosion Engineers, 1974), pp. 389-390). Carbonic acid is generated via two mechanisms in the DIO₃ process: 1) CO₂ is added to the DIO₃ mixture as a radical scavenger to maximize the lifetime of the ozone in solution; and 2) ozone reacting with photoresist leads to a CO₂ by-product. As a result, copper can be oxidized using ozone and subsequently dissolved in the acidic mixture. Therefore, we have incorporated two corrosion inhibitors into our DI mixture dispensed directly onto the wafers. Alternatively, the DI mixture may incorporate one or more bases, optionally in combination with one or more corrosion inhibitors.

Table IV shows the copper loss and visible inspection results for the DI ozone process with and without the chemical inhibitors. The DI Ozone process with no chemical inhibitors leads to visible surface oxidation and a measured copper loss of 33.5 Å. Inhibitor A resulted in a 68% decrease in copper loss to 10.7 Å. Inhibitor B was then added to the DI mixture to further bind the copper species on the surface reducing the oxidation of copper species in a competing reaction with ozone. The DI mixture using inhibitors A+B resulted in a 97% decrease in copper loss to 1.0 Å. A slight haze was observed on the wafers processed with inhibitors that is believed to be surface oxide. The surface oxide is readily removed using dilute HF or commercial residue removal chemistries (e.g., ST-250™ from ATMI, Danbury, Conn., or DEERCLEAN™ LK-1 from Kanto Chemical Company, Inc., Tokyo, Japan).

TABLE IV
Cu Loss Measurements for DIO₃ Photoresist Strip Process.

| Process | Blanket Cu Loss (Å) | Surface Oxidation |
|---|---|---|
| DIO₃ | 33.5 | Visible Surface Oxidation |
| DIO₃ + Inhibitor A | 10.7 | Slight Haze |
| DIO₃ + Inhibitor A + | 1.0 | Slight Haze |
| Inhibitor B | | |

We observed that as the porosity increases in low-k materials the ash process can lead to significant material damage in the form of film densification. The densification, in turn, results in dielectric degradation. Clean and HMDS restoration processes can significantly improve the k-value in porous films (k=2.2); however, film densification is irreversible and the as-deposited k-values cannot be recovered. In contrast, the present invention provides a substantially non-damaging wet-strip process which selectively removes photoresist without unduly degrading low k material properties or significantly removing copper.

What is claimed is:

1. A method of processing one or more wafer-like objects, comprising the step of causing ozone to contact the one or more wafer-like objects at a pH greater than about 7.5.

2. The method of claim 1, wherein the one or more wafer-like objects include an exposed copper feature.

3. A method of processing one or more wafer-like objects, comprising the step of causing ozone to contact the one or more wafer-like objects while the wafer-like objects are wetted with an aqueous base.

4. The method of claim 3, wherein the aqueous base comprises aqueous TMAH.

5. The method of claim 3, wherein the aqueous base comprises aqueous KOH.

6. The method of claim 3, wherein the aqueous base comprises a buffer.

7. The method of claim 3, wherein the aqueous base comprises a corrosion inhibitor.

8. The method of claim 7, wherein the aqueous base comprises aqueous ammonia.

9. The method of claim 3, wherein the aqueous base comprises aqueous ammonia.

10. The method of claim 3, wherein the ozone is supplied as a solute in an aqueous solution and wherein the aqueous solution further comprises a corrosion inhibitor.

11. The method of claim 10, wherein the corrosion inhibitor comprises uric acid or a derivative thereof.

12. The method of claim 10, wherein the corrosion inhibitor comprises benzotriazole or a derivative thereof.

13. The method of claim 3, wherein the one or more wafer-like objects are positioned in a processing chamber and wherein the ozone and the aqueous base are separately introduced into the processing chamber.

14. The method of claim 13, wherein the ozone is introduced into the chamber as a dissolved constituent of a DIO₃ composition.

15. The method of claim 14, wherein the DIO₃ composition is splashed into the processing chamber under conditions such that at least a portion of the dissolved ozone outgases from the DIO₃ composition and then contacts the wafer-like objects.

16. The method of claim 3, wherein the one or more wafer-like objects include an exposed copper feature.

17. A system for treating a wafer-like object including an exposed copper feature, comprising:
a chamber in which the wafer-like object is positioned during a treatment;
a first fluid material dispensed into the chamber, said first fluid material comprising ozone; and
a second fluid material separately dispensed into the chamber, said second fluid material having a pH greater than about 7.5 and being dispensed in a manner effective to help establish a basic environment proximal to the exposed copper feature.

18. A system for treating a wafer-like object including an exposed copper feature, comprising:
a chamber in which the wafer-like object is positioned during a treatment;
a first fluid material dispensed into the chamber, said first fluid material comprising ozone; and
a second fluid material separately dispensed into the chamber, said second fluid material comprising an aqueous base.

19. A system for treating a wafer-like object, comprising:
a chamber in which the wafer-like object is positioned during a treatment;
a first pathway through which an ozone-containing material is dispensed into the chamber;
a second pathway through which an aqueous base is dispensed into the chamber in a manner effective to wet the wafer-like object; and
program instructions causing the ozone-containing material and the aqueous base to be dispensed into the chamber in a manner such that ozone contacts the wafer-like object under alkaline conditions.

20. A system for treating a wafer-like object, comprising:
a chamber in which the wafer-like object is positioned during a treatment;
a first pathway through which an ozone-containing material is dispensed into the chamber;
a second pathway through which an aqueous base is dispensed into the chamber in a manner effective to wet the wafer-like object; and
program instructions causing the ozone-containing material and the aqueous base to be co-dispensed into the chamber during at least a portion of the treatment.

21. A method of treating a wafer-like object having an exposed copper feature, comprising the steps of:
positioning the wafer-like object on a rotating support in a processing chamber;
spraying an aqueous base onto the wafer-like object; and
dispensing a material comprising ozone into the processing chamber.

22. A method of treating a wafer-like object comprising a low-k dielectric material, comprising the step of causing ozone to contact the one or more wafer-like objects.

23. The method of claim 22, wherein the step of causing ozone to contact the one or more wafer-like objects occurs while the wafer-like objects are wetted with an aqueous base.
